(19) United States
(12) Patent Application Publication
(10) Pub. No.: US 2005/0236691 A1
(43) Pub. Date: Oct. 27, 2005

(54) Semiconductor device and manufacturing method for the same

(75) Inventor: Yasuhiro Shimada, Muko-shi (JP)

Correspondence Address: MCDERMOTT WILL & EMERY LLP, 600 13TH STREET, N.W., WASHINGTON, DC, 20005-3096, US

(73) Assignee: Matsushita Electric Industrial Co., Ltd.

(21) Appl. No.: 11/107,740

(22) Filed: Apr. 18, 2005

(30) Foreign Application Priority Data
Apr. 21, 2004 (JP) 2004-125915

(51) Int. Cl. H01L 29/00

(52) U.S. Cl. 257/536

(57) ABSTRACT

A manufacturing method for a semiconductor device that includes a crystal of metal-insulator phase transition material as a resistor, the method having the steps of forming an electrode on a semiconductor substrate, forming an insulating film on the electrode, forming a through-hole in the insulating film so as to expose the electrode, and housing the crystal in the through-hole so as to contact the electrode.

This application is based on application no. 2004-125915 filed in Japan, the content of which is hereby incorporated by reference.

### BACKGROUND OF THE INVENTION

1. Field of the Invention

The present invention relates to semiconductor devices that uses metal-insulator phase transition material as resistors and a manufacturing method for the same, and in particular to a technique for reducing damage caused to the resistors.

2. Related Art

Metal-insulator phase transition material, which has been attracting attention in recent years as semiconductor material, adopts a metallic and thus low-resistance state at temperatures above the transition temperature, and adopts an insulator and thus high-resistance state at temperatures below the transition temperature. The phase transition of metal-insulator phase transition material is also caused by the application of an electric field (e.g. see D. M. Newns, J. A. Misewich, C. C. Tsuei, A Gupta, B. A. Scott, and A. Schrott, “Mott transition field effect transistor”, Applied Physics Letters Vol. 73(6), pp. 780-782, Aug. 10, 1998).

Various types of semiconductor devices are being developed using metal-insulator phase transition material with advantage being taken of these properties, an example of which is a semiconductor memory for storing information in devices that apply metal-insulator phase transition material as resistors. These devices are maintained in a state of conductance or insulation when a high voltage is applied, according to the polarity of the applied voltage and the type and processing method of the metal-insulator phase transition material. In other words, it is possible to store 1-bit of information depending on whether a device is in a conductance state or an insulation state.

FIGS. 1A and 1B show a manufacturing method for such a device. Firstly, as shown in FIGS. 1A, an insulating layer 81, an electrode 82, a resistor layer 83 formed from metal-insulator phase transition material, and an electrode 84 are layered in order on a supporting substrate 80, with a photo-resist mask 85 being formed on electrode 84.

Etching is then performed using plasma etching, after which photo-resist mask 85 is removed to obtain a device 86 as shown in FIG. 1B (e.g. see Japanese Patent Application Publication No. 2003-137553).

However, when plasma etching is used, resistor layer 83 is internally damaged because of the spraying of large quantities of active species such as reactive radicals, resulting in the formation of damaged regions 83d that no longer exhibit the properties of metal-insulator phase transition material. The effective area of device 86 is thus reduced.

The extent of damaged regions 83d in resistor layer 83 is determined solely by the manufacturing method for the device, and extends to a depth of anywhere from a few dozen to a few hundred nanometers in from the wall surface of device 86. Since this depth is not dependent on the size (area) of the device, the reduction in effective area caused by the formation of damaged regions 83d can no longer be ignored when the area of the device falls below 1 μm².

Even recovery annealing performed to decrease damaged regions 83d is not effective in completely eliminating these damaged regions. Also, recovery annealing requires that a temperature the same as the crystallization temperature of metal-insulator phase transition material be applied, which adversely affects other parts of the semiconductor memory, inviting thermal deterioration of the interlayer wiring, for example.

Furthermore, difficulties have been encountered in controlling the crystal orientation of the metal-insulator phase transition material to be in a direction that allows effective metal-insulator phase transition to occur, given that polycrystallization is unavoidable because of resistor layer 83 being formed using a sputtering or sol-gel method, which obstructs the isotropization of the crystal orientation.

### SUMMARY OF THE INVENTION

The present invention, which was arrived at in view of the above problems, aims to provide a semiconductor device that uses metal-insulator phase transition material and a manufacturing method for the same, the metal-insulator phase transition material being a single crystal and not having a damaged area formed therein.

To achieve this object, a manufacturing method pertaining to the present invention is for a semiconductor device that includes a crystal of metal-insulator phase transition material as a resistor, and has the steps of forming an electrode on a semiconductor substrate, forming an insulating film on the electrode, forming a through-hole in the insulating film so as to expose the electrode, and housing the crystal in the through-hole so as to contact the electrode.

This enables the amount of etching performed on the resistor to be reduced because of the crystal being selectively placed on the electrode in forming a device. A highly efficient and detailed device can thus be provided because of being able to suppress the occurrence of damaged areas in the resistor portion. Note that “housing” is here used to refer to the placing or filling of one or a plurality of crystals in the through-hole so that the space of the through-hole is substantially occupied by the crystal(s).

In this case, it is ideal, for example, if the crystal is a single crystal having an electric charge and the crystal is positioned in the through-hole by placing the crystal under an electric field directed toward the electrode. Alternatively, the crystal may also be positioned in the through-hole by applying a mechanical vibration to the crystal or by irradiating an energy beam. The selective placement of the crystal on the electrode in forming a device is possible using any of these methods.

Also, each through-hole may be filled with one or more crystals.

Here, the manufacturing method pertaining to the present invention may further include the steps of covering the crystal on the electrode with a further insulating film, removing part of the further insulating film so as to expose part of the crystal, and forming a further electrode so as to be electrically connected to the exposed part of the crystal.

This enables the short-circuiting of the first and second electrodes to be reliably prevented, and a reliable electrical connection to be established between the second electrode and the particle made from metal-insulator phase transition material.

Here, the crystal may be baked to be a crystalline phase that represents an insulating phase. This enables the high-temperature processing performed on the semiconductor substrate in order to crystallize the metal-insulator phase transition material to be omitted from the processes performed in forming a device.

Here, the crystal may be one of a vanadium trioxide crystal, a vanadium dioxide crystal, a crystal consisting mainly of vanadium trioxide or vanadium dioxide, and a crystal consisting mainly of an alloy of vanadium trioxide and vanadium dioxide. Alternatively, the crystal may be formed from a material expressed by the general formula A₁₋ₓBₓMn_{z}O_{w}, where A is a rare earth element or a group V element, B and C are alkaline earth elements, and x, y, z and w express an arbitrary chemical composition ratio that includes 0.

The crystal may also be formed from a material expressed by the general formula A₁₋ₓ(B_{1-y}C_{y})ₓMn_{z}O_{w}, where A is a rare earth element or a group V element, B and C are alkaline earth elements, and x, y, z and w express an arbitrary chemical composition ratio that includes 0. This enables a device exhibiting excellent metal-insulator phase transition properties to be obtained.

Here, the crystal may be particle shaped, and the standard deviation of the particle diameter of the crystal may be less than or equal to an average value of the particle diameter. This enables the selectivity of crystal placement and the homogeneity of device electrical characteristics to be improved.

Alternatively, a manufacturing method pertaining to the present invention is for a semiconductor device that includes a single crystal of metal-insulator phase transition material as a resistor, and has the steps of forming an electrode on a semiconductor substrate, and adhering the single crystal to the electrode by electrophoresis, with the electrode immersed in a dispersion for liquid dispersing the single crystal. It is possible even with this structure to suppress the occurrence of damaged areas in the resistor portion, and thus provide a highly efficient and detailed device.

Here, the single crystal may be monodispersed within the dispersion. It is possible with this structure to place a plurality of single crystals on a single electrode, and thus prevent variation in the capacitance between devices.

Here, the manufacturing method pertaining to the present invention may further include the steps of covering the single crystal with a further insulating film, with the single crystal adhered to the electrode, removing part of the further insulating film so as to expose part of the single crystal, and forming a further electrode so as to be electrically connected to the exposed part of the single crystal. This enables the short-circuiting the first and second electrodes to be reliably prevented, and a reliable electrical connection to be established between the second electrode and the particle made from metal-insulator phase transition material.

Here, the single crystal may be baked to be a crystalline phase that represents an insulating phase. This enables the high-temperature processing performed on the semiconductor substrate in order to crystallize the metal-insulator phase transition material to be omitted from the processes performed in forming the device.

Note that the single crystal may be one of a vanadium trioxide crystal, a vanadium dioxide crystal, a crystal consisting mainly of vanadium trioxide or vanadium dioxide, and a crystal consisting mainly of an alloy of vanadium trioxide and vanadium dioxide, or the single crystal may be formed from a material expressed by the general formula A₁₋ₓBₓMn_{z}O_{w}, where A is a rare earth element or a group V element, B and C are alkaline earth elements, and x, y, z and w express an arbitrary chemical composition ratio that includes 0.

Alternatively, the single crystal may be formed from a material expressed by the general formula A₁₋ₓ(B_{1-y}C_{y})ₓMn_{z}O_{w}, where A is a rare earth element or a group V element, B and C are alkaline earth elements, and x, y, z and w express an arbitrary chemical composition ratio that includes 0. This enables a device exhibiting excellent metal-insulator phase transition properties to be obtained.

Here, the single crystal may be particle shaped, and the standard deviation of the particle diameter of the single crystal may be less than or equal to an average value of the particle diameter. This enables the selectivity of crystal placement and the homogeneity of device electrical characteristics to be improved.

A semiconductor device pertaining to the present invention includes a single crystal of metal-insulator phase transition material as a resistor. This enables a device exhibiting excellent metal-insulator phase transition properties to be obtained by controlling the crystal orientation.

Here, the single crystal may be baked to be a crystalline phase that represents an insulating phase. This enables the high-temperature processing performed on the semiconductor substrate in order to crystallize the metal-insulator phase transition material to be omitted from the processes performed in forming a device.

Here, the single crystal may be one of a vanadium trioxide crystal, a vanadium dioxide crystal, a crystal consisting mainly of vanadium trioxide or vanadium dioxide, and a crystal consisting mainly of an alloy of vanadium trioxide and vanadium dioxide.

The single crystal may also be formed from a material expressed by the general formula A₁₋ₓBₓMn_{z}O_{w}, where A is a rare earth element or a group V element, B and C are alkaline earth elements, and x, y, z and w express an arbitrary chemical composition ratio that includes 0, or from a material expressed by the general formula A₁₋ₓ(B_{1-y}C_{y})ₓMn_{z}O_{w}, where A is a rare earth element or a group V element, B and C are alkaline earth elements, and x, y, z and w express an arbitrary chemical composition ratio that includes 0.

Here, the single crystal may be particle shaped, and the standard deviation of the particle diameter of the single crystal may be less than or equal to an average value of the particle diameter. This enables the selectivity of crystal placement and the homogeneity of device electrical characteristics to be improved.

The present invention also enables a device exhibiting excellent metal-insulator phase transition properties to be obtained because of the crystal orientation of the resistors being coordinated so as to be orthogonal to the main surface of the electrode in a device. The writing and reading characteristics of data in memory cells are thus markedly improved.

Furthermore, being able to realize a memory having an arbitrary number of device array layers enables the placement density of memory cells to be improved by placing memory cell arrays three-dimensionally.

### BRIEF DESCRIPTION OF THE DRAWINGS

These and other objects, advantages, and features of the invention will become apparent from the following description thereof taken in conjunction with the accompanying drawings, which illustrate specific embodiments of the present invention.

In the drawings:

FIGS. 1A & 1B show a manufacturing method for a device pertaining to the prior art;

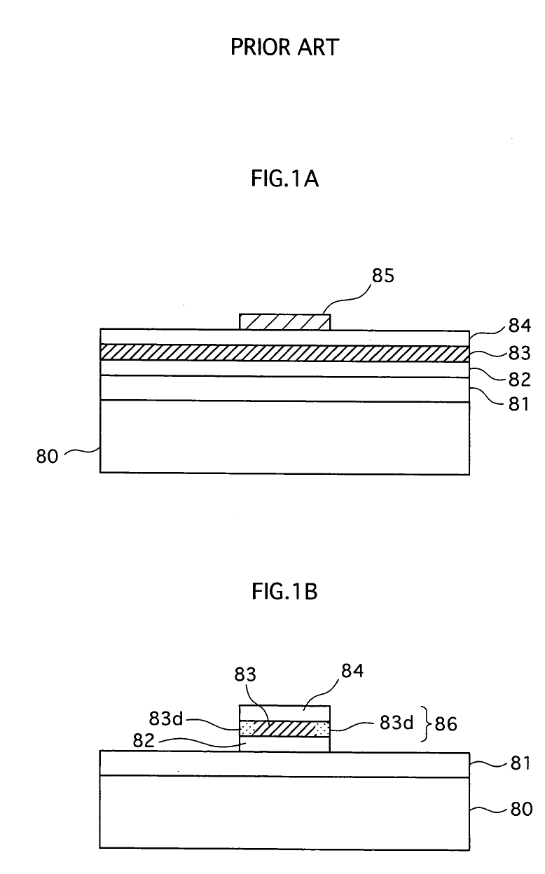

FIG. 2 is a circuit diagram of a semiconductor memory pertaining to an embodiment 1 of the present invention;

FIG. 3 is a cross-sectional view showing a device structure in a semiconductor memory 1 pertaining to embodiment 1 of the present invention;

FIG. 4 shows the selective placement of resistor particles 100b on electrodes 100c pertaining to embodiment 1 of the present invention;

FIG. 5 is a schematic view showing a process for selectively placing resistor particles 100b on electrodes 100c pertaining to embodiment 1 of the present invention;

FIG. 6 is a cross-sectional view showing semiconductor memory 1 after the formation of electrodes 100a pertaining to embodiment 1 of the present invention;

FIGS. 7A-7E show processes for selectively placing resistor particles of a semiconductor memory pertaining to an embodiment 2 of the present invention; and

FIG. 8 is a cross-sectional view showing the structure of a semiconductor memory pertaining to an embodiment 3 of the present invention.

### DETAILED DESCRIPTION OF THE PREFERRED EMBODIMENTS

Preferred embodiments of a semiconductor device pertaining to the present invention are described below with reference to the drawings, taking a semiconductor memory as an example.

### 1. EMBODIMENT 1

Described below is a semiconductor memory pertaining to an embodiment 1 of the present invention.

1-1. Circuit Structure of Semiconductor Memory

The circuit structure of a semiconductor memory pertaining to the present embodiment is described firstly.

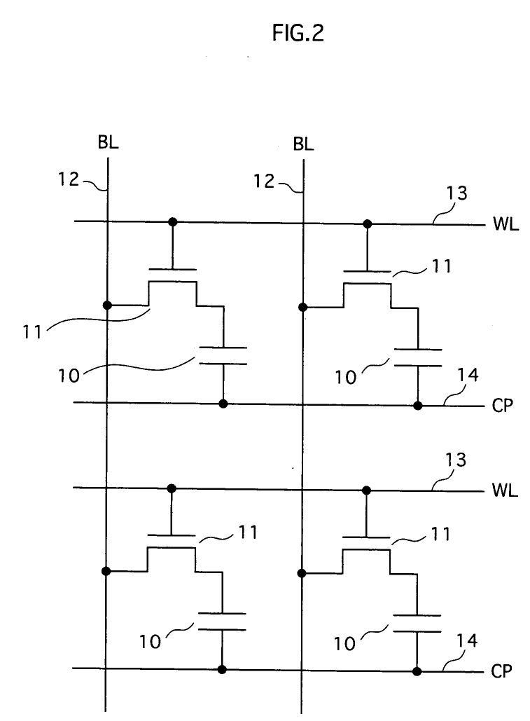

FIG. 2 is a circuit diagram of a main portion of the circuit structure of a semiconductor memory pertaining to the present embodiment. As shown in FIG. 2, semiconductor memory 1 includes devices 10, transistors 11, bit lines 12, word lines 13, and cell plate lines 14.

Here, devices 10 include a resistor layer that employs metal-insulator phase transition material, one electrode of the device being connected to a source electrode of a respective transistor 11, while the other electrode is connected to a respective cell plate line 14. A drain electrode of each transistor 11 is connected to a respective bit line 12, and a gate electrode is connected to a respective word line 13.

According to this circuit structure, a write voltage is applied between bit lines 12 and cell plate lines 14 after applying a voltage to transistors 11 via word lines 13 to place the transistors in a conductive (ON) state, which thereby places devices 10 in a conductive state, for example. This conductive state continues for a given time period even after application of the write voltage has been stopped. This continuous time period is determined based on the material and processing method used for the resistor layer, and the size and application time of the applied voltage. The conductive state is not affected by the application of a read voltage, which is lower that the write voltage. Reversing the state of devices 10 between conductive and insulated (nonconductive) is also possible by reversing the polarity of the applied voltage.

1-2. Device Structure of Semiconductor Memory

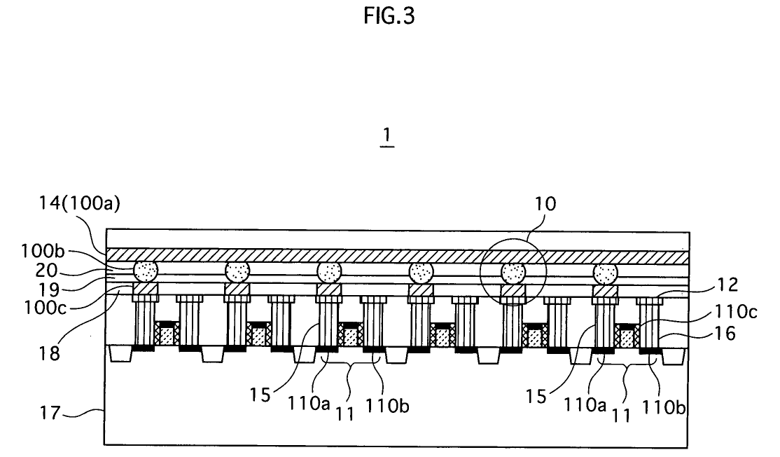

The device structure of semiconductor memory 1 is described next. FIG. 3 is a cross-sectional view showing the device structure of semiconductor memory 1. As shown in FIG. 3, semiconductor memory 1 adopts a stack structure. Each device 10 includes an electrode 100a, an electrode 100c and a resistor particle 100b. Electrode 100a is integral with cell plate line 14. Electrode 100c is disposed opposite electrode 100a with resistor particle 100b sandwiched therebetween, and connected to source electrode 100a of transistor 11 via a contact plug 15. A drain electrode 110b of each transistor 11 is connected to bit line 12 via a contact plug 16. A gate electrode 110c is connected to word line 13 (not depicted). A memory cell array is structured by arranging a plurality of these memory cells.

1-3. Material Used for Resistor Particles 100b

The material used for resistor particles 100b is described next. As stated above, resistor particles 100b are made from metal-insulator phase transition material, particularly a single crystal.

Specifically, resistor particles 100b may be a vanadium trioxide crystal (V₂O₃), a vanadium dioxide crystal (VO₂), a crystal consisting mainly of vanadium trioxide or vanadium dioxide, and a crystal consisting mainly of an alloy of vanadium trioxide and vanadium dioxide.

Also, a metal-insulator phase transition material expressed by the general formulas A₁₋ₓBₓMn_{z}O_{w} or A₁₋ₓ(B_{1-y}C_{y})ₓMn_{z}O_{w} maybe used. Here, “A” in the general formulas expresses a rare earth element such as lanthanum (La), neodymium (Nd), cerium (Ce) and praseodymium (Pr), or a group V element such as vanadium (V), while “B” and “C” express alkaline earth elements such as calcium (Ca), strontium (Sr) and barium (Ba). An arbitrary chemical composition ratio that includes 0 is expressed by the indexes x, y, z and w.

To form resistor particles 10b, a metal-insulator phase transition material that includes a number of the above materials is firstly vapor phase decomposed and oxidized, and the oxidized material is then baked.

1-4. Selective Placement of Resistor Particles 100b

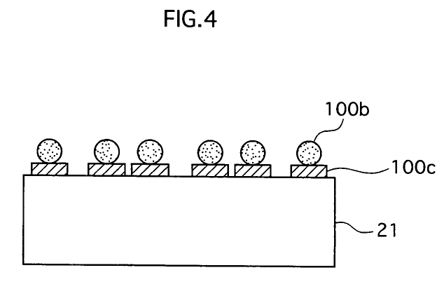

As described above, regions of the resistor layer are damaged in the prior art because of the use of etching to shape the formed resistor layer. In contrast, etching is not required in the present embodiment because of the selective placement of resistor particles 100b on electrode 100c, thus preventing regions of the resistor layer from being damaged. FIG. 4 shows the selective placement of resistor particles 100b on electrodes 100c pertaining to the present embodiment. As shown in FIG. 4, resistor particles 100b in the present embodiment are selectively placed on electrodes 100c formed on a semiconductor substrate 21. Note that semiconductor substrate 21 includes transistors 11 and the like, although these have been omitted from the diagram.

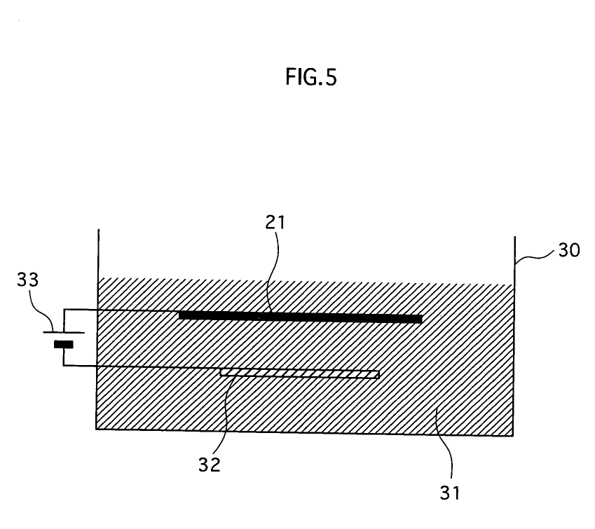

The following method is given as an exemplary method for selectively placing resistor particles 100b on electrodes 100c. FIG. 5 is a schematic view showing a process for selectively placing resistor particles 100b on electrodes 100c. As shown in FIG. 5, semiconductor substrate 21 on which electrodes 100c are formed is immersed in a dispersion 31 filled in a liquid-phase processing bath 30. A processing electrode 32 is disposed in dispersion 31 opposite electrodes 100c, with a DC (direct current) power supply 33 being connected to semiconductor substrate 21 and processing electrode 32.

Dispersion 31 disperses resistor particles 100b in an organic solvent such as acetone or ethanol, with the acidity being adjusted so that resistor particles 100b monodisperse. Resistor particles 100b are baked to be a crystalline phase that exhibits ferroelectricity, before being mixed in the liquid.

Resistor particles 100b are single crystals, and their dielectric constant is highly anisotropic. Resistor particles 100b thus migrate toward electrodes 100c when an electric field is applied between processing electrode 32 and electrodes 100c formed on semiconductor substrate 21 using DC power supply 33. Because the dipole moment of resistor particles 100b in this case is parallel with the crystal axis, resistor particles 100b are selectively coordinated so that the orientation in which the metal-insulator phase transition of the particles occurs most effectively is parallel with the applied electric field; that is, orthogonal to the surface of electrodes 100c.

Note that modifying resistor particles 100b in advance with a thiol group or the like facilitates the selective placement of resistor particles 100b on electrodes 100c.

Next, insulating film 20 is deposited using chemical vapor deposition (CVD) or a spin-on-glass technique, so as to cover resistor particles 100b. The surface of insulating film 20 is then ground using an etch-back technique or chemical mechanical polishing (CMP) until part of resistor particles 100b is uniformly exposed. Electrodes 100a are formed on this ground surface.

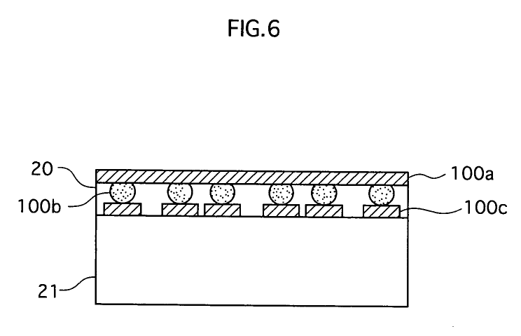

FIG. 6 is a cross-sectional view showing semiconductor memory 1 after the formation of electrodes 100a. As shown in FIG. 6, electrodes 100a and electrodes 100c are formed so as to intersect one another orthogonally in a longitudinal direction, with devices 10 being located at the intersection of electrodes 100a and 100c when semiconductor memory 1 is viewed in plan.

The fact that resistor particles 100b are single crystals and the crystal orientation of the particles is controlled when devices 10 are formed in this manner enables the metal-insulator phase transition material of the particles to be most effectively used.

Also, making resistor particles 100b uniform in shape enables the processing of devices 10 to be reduced. The result is the elimination of damaged regions and the effective use of metal-insulator phase transition material, all of which amounts to a marked improvement in the writing and reading characteristics of data in memory cells.

### 2. EMBODIMENT 2

An embodiment 2 of the present invention is described next. While a semiconductor memory pertaining to the present embodiment includes a similar structure to the semiconductor memory pertaining to embodiment 1, a difference lies in the method for selectively placing resistor particles. The present embodiment is thus described only in terms of the manufacturing method for the devices having resistor particles.

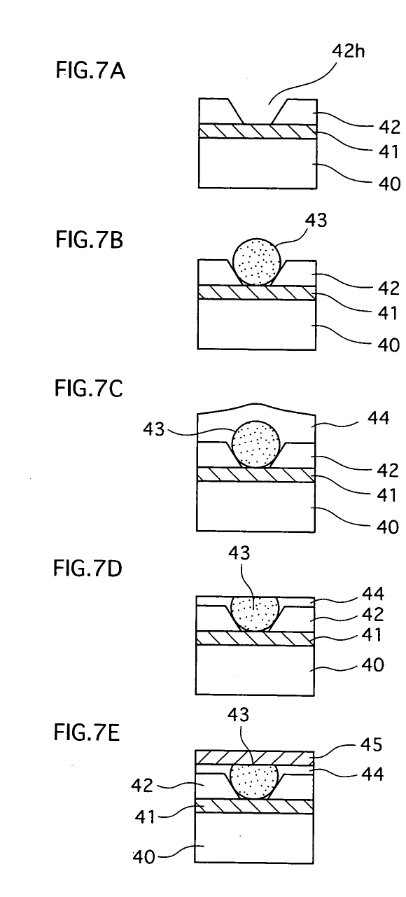

FIGS. 7A to 7E show the processes for selectively placing resistor particles with respect to the semiconductor memory pertaining to the present embodiment. In FIGS. 7A to 7E, the manufacturing method begins from a state in which components corresponding to transistors 11, electrodes 100c and the like in embodiment 1 have already been made.

Firstly, as shown in FIG. 7A, an electrode 41 is formed on a semiconductor substrate 40, and an insulating film 42 is then formed on electrode 41. A through-hole 42h is formed in insulating film 42, exposing part of electrode 41 via through-hole 42h. Through-hole 42h is large enough to enable a resistor particle to be housed in contact with electrode 41.

After the above processing, semiconductor substrate 40 is placed in a liquid-phase processing bath as described in embodiment 1, causing resistor particles 43 to migrate. The change in flatness of insulating film 42 at the location of through-hole 42h means that the van der Waals potential around through-hole 42h varies greatly in comparison to surrounding areas. The van der Waals potential interacts with the dipole moment of resistor particles 43 to selectively attach resistor particles 43 to electrodes 41 (FIG. 7B).

Also, the fact that the dipole moment of resistor particles 43 is parallel with the crystal axis means that resistor particles 43 are selectively coordinated so that the orientation in which the metal-insulator phase transition of the particles occurs most effectively is parallel with the applied electric field; that is, orthogonal to the surface of electrodes 41. Note that modifying resistor particles 43 in advance with a thiol group or the like facilitates the selective placement on electrodes 41.

Next, an insulating film 44 is deposited using CVD or a spin-on-glass technique, so as to cover resistor particles 43 (FIG. 7C). The surface of insulating film 44 is then ground using an etch-back technique or CMP until part of resistor particles 43 is uniformly exposed (FIG. 7D). Electrodes 45 are formed on this ground surface (FIG. 7E). Electrodes 45 are formed so as to intersect electrodes 41 orthogonally in a longitudinal direction, with devices 1 being located where electrodes 45 overlap electrodes 41 when semiconductor memory 1 is viewed in plan.

The fact that resistor particles 43 formed in this manner are single crystals and the crystal orientation of the particles is controlled enables the metal-insulator phase transition material of the particles to be most effectively used. Also, making resistor particles 43 uniform in shape enables the processing of devices 10 to be reduced. The result is the elimination of damaged regions and the effective use of metal-insulator phase transition material, all of which amounts to a marked improvement in the writing and reading characteristics of data in memory cells.

In particular, the selectivity of resistor particle placement and the homogeneity of device electrical characteristics improve markedly when the standard deviation expressing the unevenness in the particle diameter of resistor particles 43 is at or below the average particle diameter.

Note that in the processes (FIGS. 7A-7B) for selectively placing resistor particles 43 at a desired position on electrodes 41, the translational energy at the substrate surface of resistor particles 43 is increased by applying a mechanical vibration such as supersonic waves to semiconductor substrate 40, thus enabling the selectively to be further increased. Similar effects are obtained by irradiating an energy beam such as a laser or an electron beam onto resistor particles 43.

The method for housing resistor particles 43 within through-holes 42h formed in insulating film 42 stated in the present embodiment is also effective in filling a single through-hole 42h with a plurality of resistor particles 43.

### 3. EMBODIMENT 3

Embodiment 3 of the present invention is described next. A feature of a semiconductor memory pertaining to the present embodiment is, in addition to the structure of the semiconductor memories pertaining to embodiments 1 and 2, the three-dimensional placement of memory arrays, thus improving the placement density of memory cells.

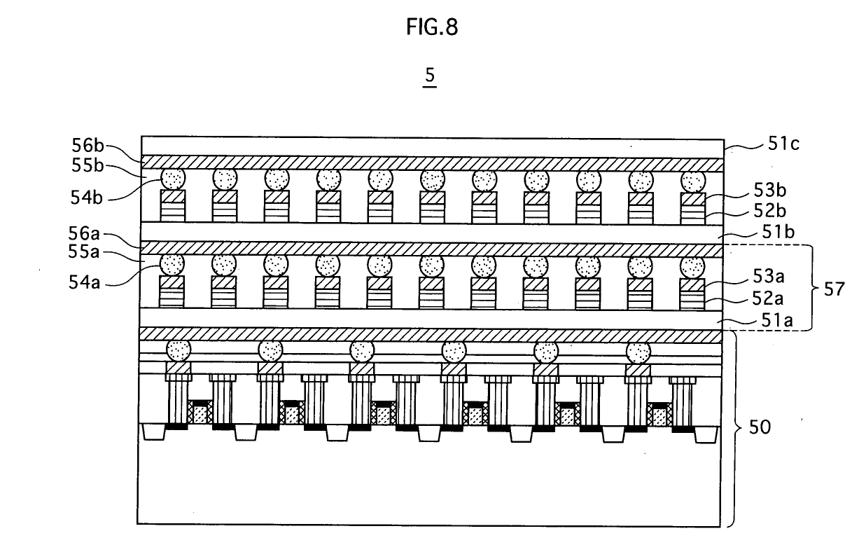

FIG. 8 is a cross-sectional view showing the structure of a semiconductor memory pertaining to the present embodiment. In the present embodiment, as shown in FIG. 8, firstly a semiconductor memory 50 the same as semiconductor memory 1 shown in FIG. 3 is manufactured, and an interlayer insulating film 51a is formed on semiconductor memory 50. After polishing interlayer insulating film 51a to a flat surface, semiconductor thin films 52a are formed on interlayer insulating film 51a, and electrodes 53a are formed on semiconductor thin film 52a. Semiconductor thin film 52a and electrodes 53a are then etched into the shape shown in FIG. 8, to thus form metal-insulator Schottky barrier diodes.

Resistor particles 54a are then selectively placed on electrodes 53a using the method stated in embodiments 1 and 2, and an insulating film 55a is deposited so as to cover resistor particles 54a. The surface of insulating film 55a is then ground using an etch-back technique or CMP so as to uniformly expose part of resistor particles 54a, and electrodes 56a are formed on the ground surface. Electrodes 56a are formed so as to be orthogonal to electrodes 53a in a longitudinal direction, and so that the intersection of electrodes 56a with electrodes 53a overlaps with resistor particles 54a when semiconductor memory 50 is viewed in plan. Devices 57 are thus formed as a result.

Repeating these processes and then forming interlayer insulating film 51a at the end enables a plurality of layered device arrays to be formed. Being able to form a memory that includes an arbitrary number of device array layers enables memory cell arrays to be placed three-dimensionally, and thus for improvements in the placement density of memory cells.

### 4. MODIFICATIONS

The present invention, while having been described above based on the preferred embodiments, is of course not limited to these embodiments, it being possible to implement the following modifications.

(1) Although the preferred embodiments are described above taking only a semiconductor memory as an example, the present invention is needless to say not limited to this, and may be applied in semiconductor devices other than a semiconductor memory. That is, as long as the semiconductor device employs metal-insulator phase transition material in the resistors, the above effects can be obtained through application of the present invention in semiconductor devices that carry out functions including switching, logical operations, learning, and temperature detection.

(2) Although not particularly referred to in the preferred embodiments, the present invention is needless to say not limited to the above semiconductor memories, and may be a method for manufacturing the above semiconductor memories. Also, given that a feature of the present invention is a manufacturing method for devices that use metal-insulator phase transition material in the resistors, the above effects can be obtained even in the case of the manufacturing method pertaining to the present invention being applied in the manufacture of a semiconductor device as stated in modification (1) above, as long as the semiconductor device employs such resistors.

(3) Although the preferred embodiments are described above taking the case of each device being structured by a single resistor particle as an example, the present invention is needless to say not limited to this, and the number of resistor particles per device may be adjusted by adjusting the size of the electrodes that the resistor particles contact.

(4) Although the resistor particles in the preferred embodiments are schematically represented as a sphere, the present invention is needless to say not limited to this, and may adopt a shape other than a sphere. Even when the particle shape is other than spherical, the plurality of resistor particles formed in a single semiconductor device preferably are uniform in shape and size, thus enabling variation in the capacitance between devices to be suppressed.

Although the present invention has been fully described by way of examples with reference to the accompanying drawings, it is to be noted that various changes and modifications will be apparent to those skilled in the art. Therefore, unless such changes and modifications depart from the scope of the present invention, they should be construed as being included therein.

1. A manufacturing method for a semiconductor device that includes a crystal of metal-insulator phase transition material as a resistor, comprising the steps of:
forming an electrode on a semiconductor substrate;
forming an insulating film on the electrode;
forming a through-hole in the insulating film so as to expose the electrode; and
filling the through-hole with the crystal so as to contact the electrode.

2. The manufacturing method of claim 1, wherein
the crystal is a single crystal having an electric charge; and
in the filling step, the crystal is positioned in the through-hole by placing the crystal under an electric field directed toward the electrode.

3. The manufacturing method of claim 1, wherein in the filling step, the crystal is positioned in the through-hole by applying a mechanical vibration to the crystal.

4. The manufacturing method of claim 1, wherein in the filling step, the crystal is positioned in the through-hole by irradiating an energy beam.

5. The manufacturing method of claim 1, further comprising the steps of:
covering the crystal on the electrode with a further insulating film;
removing part of the further insulating film so as to expose part of the crystal; and
forming a further electrode so as to be electrically connected to the exposed part of the crystal.

6. The manufacturing method of claim 1, wherein the crystal is baked to be a crystalline phase that represents an insulating phase.

7. The manufacturing method of claim 1, wherein the crystal is one of a vanadium trioxide crystal, a vanadium dioxide crystal, a crystal consisting mainly of vanadium trioxide or vanadium dioxide, and a crystal consisting mainly of an alloy of vanadium trioxide and vanadium dioxide.

8. The manufacturing method of claim 1, wherein the crystal is formed from a material expressed by the general formula A₁₋ₓBₓMn_{z}O_{w}, where A is a rare earth element or a group V element, B and C are alkaline earth elements, and x, y, z and w express an arbitrary chemical composition ratio that includes 0.

9. The manufacturing method of claim 1, wherein the crystal is formed from a material expressed by the general formula A₁₋ₓ(B_{1-y}C_{y})ₓMn_{z}O_{w}, where A is a rare earth element or a group V element, B and C are alkaline earth elements, and x, y, z and w express an arbitrary chemical composition ratio that includes 0.

10. The manufacturing method of claim 1, wherein the crystal is particle shaped, and a standard deviation of a particle diameter of the crystal is less than or equal to an average value of the particle diameter.

11. A manufacturing method for a semiconductor device that includes a single crystal of metal-insulator phase transition material as a resistor, comprising the steps of:
forming an electrode on a semiconductor substrate; and
adhering the single crystal to the electrode by electrophoresis, with the electrode immersed in a dispersion for liquid dispersing the single crystal.

12. The manufacturing method of claim 11, wherein in the adhering step, the single crystal is monodispersed within the dispersion.

13. The manufacturing method of claim 11, further comprising the steps of:
covering the single crystal with a further insulating film, with the single crystal adhered to the electrode;
removing part of the further insulating film so as to expose part of the single crystal; and
forming a further electrode so as to be electrically connected to the exposed part of the single crystal.

14. The manufacturing method of claim 11, wherein the single crystal is baked to be a crystalline phase that represents an insulating phase.

15. The manufacturing method of claim 11, wherein the single crystal is one of a vanadium trioxide crystal, a vanadium dioxide crystal, a crystal consisting mainly of vanadium trioxide or vanadium dioxide, and a crystal consisting mainly of an alloy of vanadium trioxide and vanadium dioxide.

16. The manufacturing method of claim 11, wherein the single crystal is formed from a material expressed by the general formula A₁₋ₓBₓMn_{z}O_{w}, where A is a rare earth element or a group V element, B and C are alkaline earth elements, and x, y, z and w express an arbitrary chemical composition ratio that includes 0.

17. The manufacturing method of claim 11, wherein the single crystal is formed from a material expressed by the general formula A₁₋ₓ(B_{1-y}C_{y})ₓMn_{z}O_{w}, where A is a rare earth element or a group V element, B and C are alkaline earth elements, and x, y, z and w express an arbitrary chemical composition ratio that includes 0.

18. The manufacturing method of claim 11, wherein the single crystal is particle shaped, and a standard deviation of a particle diameter of the single crystal is less than or equal to an average value of the particle diameter.

19. A semiconductor device that includes a single crystal of metal-insulator phase transition material as a resistor.

20. The semiconductor device of claim 19, wherein the single crystal is baked to be a crystalline phase that represents an insulating phase.

21. The semiconductor device of claim 19, wherein the single crystal is one of a vanadium trioxide crystal, a vanadium dioxide crystal, a crystal consisting mainly of vanadium trioxide or vanadium dioxide, and a crystal consisting mainly of an alloy of vanadium trioxide and vanadium dioxide.

22. The semiconductor device of claim 19, wherein the single crystal is formed from a material expressed by the general formula A₁₋ₓBₓMn_{z}O_{w}, where A is a rare earth element or a group V element, B and C are alkaline earth elements, and x, y, z and w express an arbitrary chemical composition ratio that includes 0.

23. The semiconductor device of claim 19, wherein the single crystal is formed from a material expressed by the general formula A₁₋ₓ(B_{1-y}C_{y})ₓMn_{z}O_{w}, where A is a rare earth element or a group V element, B and C are alkaline earth elements, and x, y, z and w express an arbitrary chemical composition ratio that includes 0.

24. The semiconductor device of claim 19, wherein the single crystal is particle shaped, and a standard deviation of a particle diameter of the single crystal is less than or equal to an average value of the particle diameter.
